(19) United States
(12) Patent Application Publication
(10) Pub. No.: US 2011/0127555 A1
(43) Pub. Date: Jun. 2, 2011

(54) SOLID STATE LIGHT EMITTER WITH PHOSPHORS DISPERSED IN A LIQUID OR GAS FOR PRODUCING HIGH CRI WHITE LIGHT

(75) Inventors: Jack C. RAINS, JR., Herndon, VA (US); David P. Ramer, Reston, VA (US)

(73) Assignee: RENAISSANCE LIGHTING, INC.

(21) Appl. No.: 12/840,807

(22) Filed: Jul. 21, 2010

Related U.S. Application Data
(63) Continuation-in-part of application No. 12/629,599, filed on Dec. 2, 2009.

(51) Int. Cl. H01L 33/50

(52) U.S. Cl. 257/98; 257/E33.061

(57) ABSTRACT

A solid state white light emitting device includes a semiconductor chip for producing electromagnetic energy and may additionally include a reflector forming an optical integrating cavity. Phosphors, such as semiconductor nanophosphors dispersed in a light transmissive liquid or gas material, within the chip packaging of the solid state device itself, are excitable by the energy from the chip. The device produces output light that is at least substantially white and has a color rendering index (CRI) of 75 or higher. The white light output of the device may exhibit color temperature in one of the following specific ranges along the black body curve: 2,725±145° Kelvin; 3,045±175° Kelvin; 3,465±245° Kelvin; 3,985±275° Kelvin; 4,503±243° Kelvin; 5,028±283° Kelvin; 5,665±355° Kelvin; and 6,530±510° Kelvin.

### RELATED APPLICATIONS

This application is a continuation-in-part and claims the benefit of U.S. application Ser. No. 12/629,599, filed Dec. 2, 2009, entitled “SOLID STATE LIGHT EMITTER WITH NEAR-UV PUMPED NANOPHOSPHORS FOR PRODUCING HIGH CRI WHITE LIGHT,” the disclosure of which is entirely incorporated herein by reference.

### TECHNICAL FIELD

The present subject matter relates to solid state devices constructed to produce perceptible white light of a desirable color or spectral characteristic, for example for general lighting applications using phosphors, e.g. semiconductor nanophosphors, dispersed in a light transmissive liquid or gaseous material for converting pumping energy into visible white light, with a color rendering index (CRI) of 75 or higher and/or with a color temperature in one of several specific disclosed regions along the black body curve which provide a desirable quality of white light particularly for general lighting applications and the like.

### BACKGROUND

As costs of energy increase along with concerns about global warming due to consumption of fossil fuels to generate energy, there is an every increasing need for more efficient lighting technologies. These demands, coupled with rapid improvements in semiconductors and related manufacturing technologies, are driving a trend in the lighting industry toward the use of light emitting diodes (LEDs) or other solid state light sources to produce light for general lighting applications, as replacements for incandescent lighting and eventually as replacements for other older less efficient light sources.

The actual solid state light sources, however, produce light of specific limited spectral characteristics. To obtain white light of a desired characteristic and/or other desirable light colors, one approach uses sources that produce light of two or more different colors or wavelengths and one or more optical processing elements to combine or mix the light of the various wavelengths to produce the desired characteristic in the output light. In recent years, techniques have also been developed to shift or enhance the characteristics of light generated by solid state sources using phosphors, including for generating white light using LEDs. Phosphor based techniques for generating white light from LEDs, currently favored by LED manufacturers, include UV or Blue LED pumped phosphors. In addition to traditional phosphors, semiconductor nanophosphors have been used more recently. The phosphor materials may be provided as part of the LED package (on or in close proximity to the actual semiconductor chip), or the phosphor materials may be provided remotely (e.g. on or in association with a macro optical processing element such as a diffuser or reflector outside the LED package).

Although these solid state lighting technologies have advanced considerably in recent years, there is still room for further improvement. For example, there is always a need for alternative techniques to still further improve efficiency of solid state devices, lamps, lighting fixtures or systems, to reduce energy consumption. Also, for general lighting applications, it is desirable to provide light outputs of acceptable characteristics (e.g. white light of a desired color temperature and/or color rendering index).

### SUMMARY

From a first perspective teachings herein provide further improvements over the existing technologies using a semiconductor emitter chip and one or more phosphors, e.g. doped and/or non-doped semiconductor nanophosphors, for providing light that is at least substantially white, has a high CRI and/or exhibits a desirable color temperature characteristic. Within the solid sate device, that is to say, within the package or housing in proximity to the chip, a liquid or gas material bears the phosphor(s) which helps with efficiency and may improve appearance.

An exemplary solid state light emitting device might include a semiconductor chip for producing electromagnetic energy and a package enclosing the semiconductor chip and configured to allow emission of light as an output of the device. Semiconductor nanophosphors are dispersed in a light transmissive liquid or gas contained within the package. Each of the semiconductor nanophosphors has a respective absorption spectrum encompassing an emission spectrum of the semiconductor chip for re-emitting visible light of a different spectrum, for together producing visible light in the output of the device when the semiconductor nanophosphors are excited by electromagnetic energy from the semiconductor chip. The resulting visible light output is at least substantially white and has a color rendering index (CRI) of 75 or higher. In this example, the visible light output produced during the excitation of the semiconductor nanophosphors also exhibits a color temperature in one of the following ranges along the black body curve: 2,725±145° Kelvin; 3,045±175° Kelvin; 3,465±245° Kelvin; 3,985±275° Kelvin; 4,503±243° Kelvin; 5,028±283° Kelvin; 5,665±355° Kelvin; and 6,530±510° Kelvin.

In certain specific examples, the semiconductor chip is of a type for producing near UV electromagnetic energy, specifically in a range of 380-420 nm. Each of the semiconductor nanophosphors, dispersed in a light transmissive liquid or a gas within the package, is of a type excited in response to near UV electromagnetic energy in the range of 380-420 nm. In a specific example, the semiconductor chip is configured for producing electromagnetic energy of 405 nm. The phosphors contained in the light transmissive liquid or gas within the device package include a doped semiconductor nanophosphor of a type excited for re-emitting orange light, a doped semiconductor nanophosphor of a type for re-emitting blue light, and a doped semiconductor nanophosphor of a type for re-emitting green light. In such a case, the visible light output produced during the near UV excitation of the doped semiconductor nanophosphors has a CRI of at least 80. A doped semiconductor nanophosphor of a type for re-emitting yellowish-green or greenish-yellow light may be added to further increase the CRI.

In another example, doped semiconductor nanophosphors include red, green, blue and yellow emitting nanophosphors, excited in response to electromagnetic energy in the range of 460 nm or below. In such a case, the visible light output produced during the excitation of the doped semiconductor nanophosphors has a CRI of at least 88.

The excitation of semiconductor nanophosphors provides a relatively efficient mechanism to produce the desired white light output. The selection of the parameters of the energy for pumping the phosphors, and the selection of the doped and/or non-doped semiconductor nanophosphors to emit light having CRI in the specified range and color temperature in one of the particular ranges provides white light that is highly useful, desirable and acceptable, particularly for many general lighting applications. The semiconductor and the semiconductor nanophosphors may be utilized in any of a wide range of device designs, including those known for LED type devices.

In a new example disclosed in the detailed description and drawings, a solid state light emitting device of the type discussed herein also includes at least one reflective surface within the package forming an optical integrating cavity. The semiconductor chip is positioned and oriented so that at least substantially all direct emissions from the semiconductor chip reflect at least once within the cavity. The optical integrating cavity may be filled with a light transmissive liquid or gaseous material. The light transmissive material and a containment member configured to contain the light transmissive material within the package, such that the light transmissive material fills at least a substantial portion of the optical integrating cavity. A surface of a containment member forms an optical aperture to allow emission of light from the cavity for a light output of the device. The gas or liquid may be deployed within the package in a variety of different ways, however, in the illustrated example having the cavity, the semiconductor nanophosphors are dispersed in the light transmissive liquid or gas. The semiconductor chip is positioned and oriented relative to the cavity so that any electromagnetic energy reaching the surface of a container housing the light transmissive liquid or gas directly from the semiconductor chip impacts the surface at a sufficiently small angle as to be reflected back into the optical integrating cavity by total internal reflection at the surface of the optical aperture.

In an exemplary implementation of a solid state device, phosphors are doped and/or non-doped semiconductor nanophosphors dispersed in a light transmissive liquid or gas. With the semiconductor nanophosphors, the device may be configured such that the white light output of the solid state light emitting device exhibits color temperature in one of the following specific ranges along the black body curve: 2,725±145° Kelvin; 3,045±175° Kelvin; 3,465±245° Kelvin; 3,985±275° Kelvin; 4,503±243° Kelvin; 5,028±283° Kelvin; 5,665±355° Kelvin; and 6,530±510° Kelvin. The reflective surface may be diffusely reflective.

From a somewhat different perspective, a more specific example of a solid state light emitting device that includes a semiconductor chip, a package enclosing the semiconductor chip, a reflective surface within the package is disclosed. The chip in this specific example is of a type or structure that produces near UV electromagnetic energy, specifically in a range of 380-420 nm. The reflective surface within the package forms an optical integrating cavity. The semiconductor chip is positioned and oriented so that at least substantially all direct emissions from the semiconductor chip reflect at least once within the cavity. A containment member is configured to contain a light transmissive gas or liquid material and within the package. The light transmissive material fills at least a substantial portion of the optical integrating cavity. A surface of a containment member forms an optical aperture to allow emission of light from the cavity for a light output of the device. This type of device also includes phosphors dispersed within the light transmissive liquid or gas material. Each of the phosphors in this specific example is of a type excited in response to near UV electromagnetic energy in the range of 380-420 nm. Each of the phosphors is of a type for re-emitting visible light of a different spectral characteristic outside (having substantially no overlap with) the absorption spectra of the phosphors. When excited by near UV electromagnetic energy from the semiconductor chip, the phosphors together produce visible light in the output of the device. That visible light output is at least substantially white, and that visible light output has a color rendering index (CRI) of 75 or higher.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIGS. 1A and 1B are simplified cross-sectional views of light-emitting diode (LED) type solid state devices, which use a semiconductor LED chip and semiconductor nanophosphors within the package enclosing the semiconductor chip to produce white light of the characteristics discussed herein.

FIG. 2 is a table showing the color temperature ranges and corresponding nominal color temperatures.

FIG. 3 is a color chart showing the black body curve and tolerance quadrangles along that curve for chromaticities corresponding to the desired color temperature ranges.

FIGS. 4A and 4B are tables showing the chromaticity specifications for the nominal values and CIE color temperature (CCT) ranges.

FIG. 5 is a graph of absorption and emission spectra of a number of doped semiconductor nanophosphors.

FIG. 6 is a graph of emission spectra of three of the doped semiconductor nanophosphors, selected for use in an exemplary solid state light emitting device, as well as the spectrum of the white light produced by combining the spectral emissions from those three nanophosphors.

FIG. 7 is a graph of emission spectra of four doped semiconductor nanophosphors, in this case, for red, green, blue and yellow emissions, as the spectrum of the white light produced by combining the spectral emissions from those four phosphors.

FIGS. 8A and 8B are simplified cross-sectional views of other structures for a light-emitting diode (LED) type device, here incorporating a contained liquid or gas which substantially fills the optical integrating cavity.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

The various solid state devices disclosed herein provide efficient generation and output of visible white light of characteristics that are highly desirable in general lighting applications and the like, using electromagnetic energy from at least one semiconductor chip to pump phosphors, such as doped and/or non-doped semiconductor nanophosphors, for converting such energy into high quality visible white light.

In certain more specific examples, a device includes a semiconductor chip that produces electromagnetic energy in a range of 380-420 nm, which is a portion of the “near ultraviolet” or “near UV” part of the electromagnetic energy spectrum. Several specific examples use a near UV LED type semiconductor chip, e.g. rated to produce electromagnetic energy at 405 nm.

Phosphors, doped and non-doped semiconductor nanophosphors in several specific examples, are positioned in the chip packaging of the device for excitation by the electromagnetic energy emitted by the chip. When the phosphors are pumped or excited, the combined light output of the solid state device is at least substantially white and has a color rendering index (CRI) of 75 or higher. Although sometimes referred to below simply as white light for convenience, the light output is “at least substantially” white in that it appears as visible white light to a human observer, although it may not be truly white in the electromagnetic sense in that it may exhibit some spikes or peaks and/or valleys or gaps across the relevant portion of the visible spectrum.

In the examples using semiconductor nanophosphors, the output light of the device exhibits color temperature in one of the following specific ranges along the black body curve: 2,725±145° Kelvin; 3,045±175° Kelvin; 3,465±245° Kelvin; 3,985±275° Kelvin; 4,503±243° Kelvin; 5,028±283° Kelvin; 5,665±355° Kelvin; and 6,530±510° Kelvin. High CRI white light of a color temperature in each of these particular ranges, for example, is highly useful, desirable and acceptable for many general lighting applications. General lighting applications include, for example, illumination of spaces or areas to be inhabited by people or of objects in or around such areas. Of course, the white light emitting solid state devices may be used in a variety of other light emission applications.

Before discussing structural examples, it may be helpful to discuss the types of phosphors of interest here. Semiconductor nanophosphors are nano-scale crystals or “nanocrystals” formed of semiconductor materials, which exhibit phosphorescent light emission in response to excitation by electromagnetic energy of an appropriate input spectrum (excitation or absorption spectrum). Examples of such nanophosphors include quantum dots (q-dots) formed of semiconductor materials. Like other phosphors, quantum dots and other semiconductor nanophosphors absorb light of one wavelength band and re-emit light at a different band of wavelengths. However, unlike conventional phosphors, optical properties of the semiconductor nanophosphors can be more easily tailored, for example, as a function of the size of the nanocrystals. In this way, for example, it is possible to adjust the absorption spectrum and/or the emission spectrum of the semiconductor nanophosphors by controlling crystal formation during the manufacturing process so as to change the size of the nanocrystals. For example, nanocrystals of the same material, but with different sizes, can absorb and/or emit light of different colors. For at least some semiconductor nanophosphor materials, the larger the nanocrystals, the redder the spectrum of re-emitted light; whereas smaller nanocrystals produce a bluer spectrum of re-emitted light.

Doped semiconductor nanophosphors are somewhat similar in that they are nanocrystals formed of semiconductor materials. However, this later type of semiconductor phosphors are doped, for example, with a transition metal or a rare earth metal. The doped semiconductor nanophosphors used in several exemplary solid state light emitting devices discussed herein are configured to convert energy in a range at or below 460 nm (e.g., UV or near UV range of 380-420 nm) into wavelengths of light, which together result in high CRI visible white light emission.

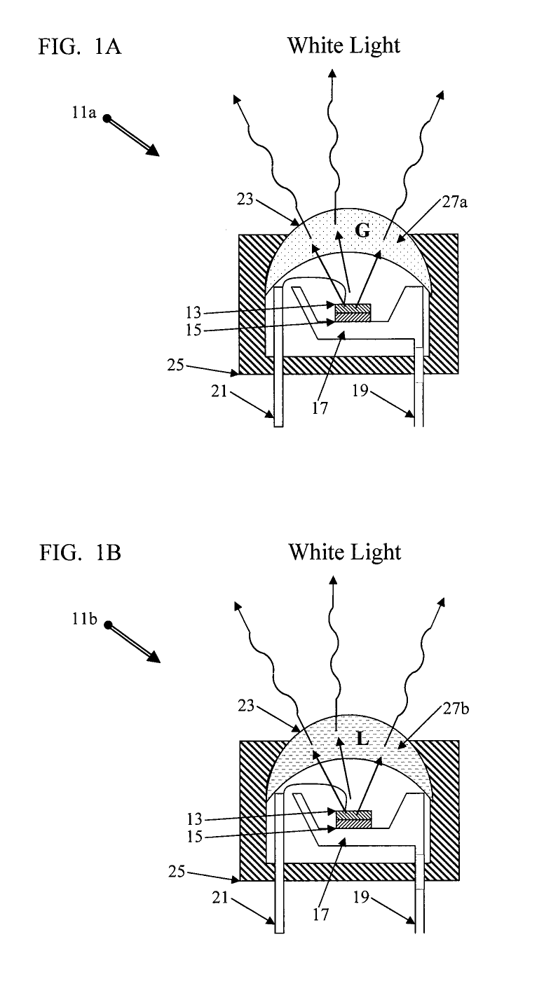

Semiconductor devices rated for a particular wavelength, such as the solid state sources 11a, 11b, exhibit emission spectra having a relatively narrow peak at a predominant wavelength, although some such devices may have a number of peaks in their emission spectra. Often, manufacturers rate such devices with respect to the intended wavelength λ of the predominant peak, although there is some variation or tolerance around the rated value, from device to device. Solid state light source devices, such as devices 11a, 11b, can have a predominant wavelength λ in the range at or below 460 nm (λ≦460 nm), for example at 405 nm (λ=405 nm) which is in the 380-420 nm near UV range. A LED used as solid state sources 11a, 11b in the examples of FIGS. 1A and 1B that is rated for a 405 nm output, will have a predominant peak in its emission spectra at or about 405 nm (within the manufacturer's tolerance range of that rated wavelength value). The devices can have additional peaks in their emission spectra.

Semiconductor nanophosphors, including doped semiconductor nanocrystal phosphors, may be grown by a number of techniques. For example, colloidal nanocrystals are solution-grown, although non-colloidal techniques are possible.

In practice, a material containing or otherwise including doped semiconductor nanophosphors, of the type discussed in the examples herein, would contain several different types of doped semiconductor nanocrystals sized and/or doped so as to be excited by the rated energy of the semiconductor chip. The different types of nanocrystals (e.g. semiconductor material, crystal size and/or doping properties) in the mixture are selected by their emission spectra and provided in proportions, so that together the excited nanophosphors provide the high CRI white light of a rated color temperature when all are excited by the energy from the chip. The doped semiconductor nanophosphors exhibit a relatively large Stokes shift, from lower wavelength absorption spectra to higher wavelength emission spectra.

In several more specific examples, each of the phosphors is of a type excited in response to near UV electromagnetic energy in the range of 380-420 nm for re-emitting visible light of a different spectral characteristic, and each of the phosphor emission spectra has little or no overlap with absorption spectra of the phosphors. In those cases, because of the sizes of the shifts, the emissions are substantially free of any overlap with the absorption spectra of the phosphors, and re-absorption of light emitted by the phosphors can be reduced or eliminated, even in applications that use a mixture of a number of such phosphors to stack the emission spectra thereof so as to provide a desired spectral characteristic in the combined light output.

Nanophosphors are dispersed in a gas or liquid in such a manner that the gas or liquid bearing the semiconductor nanophosphor(s) appears at least substantially color-neutral to the human observer when the semiconductor chip in the solid state light emitting device is off. In this way, the nanophosphor is not readily perceptible to a person viewing the solid state device when off. Clear and translucent off-state appearances are discussed, by way of examples. The nanophosphors, particularly the doped semiconductor nanophosphors, are excited by light in the near UV to blue end of the visible spectrum and/or by UV light energy. However, nanophosphors can be used that are relatively insensitive to other ranges of visible light often found in natural or other ambient white visible light. Hence, when the chip of the solid light emitting device is off, the semiconductor nanophosphor will exhibit little or no light emissions that might otherwise be perceived as color by a human observer. The medium or material chosen to bear the nanophosphor is itself at least substantially color-neutral, e.g. clear or translucent. Although not emitting, the particles of the doped semiconductor nanophosphor may have some color, but due to their small size and dispersion in the material, the overall effect is that the liquid or gaseous material with the nanophosphors dispersed therein appears at least substantially color-neutral to the human observer, that is to say it has little or no perceptible tint, when there is no excitation energy from the semiconductor chip.

As discussed, the material with the dispersed nanophosphors will be sufficiently color-neutral in that it will exhibit little or no perceptible tint. The nanophosphors may be chosen to be subject to relatively little excitation from ambient light (in the absence of energy from the solid state source). The material or medium (by itself) is chosen to have optical properties, such as absorptivity or dispersion/scattering properties that are generally independent of wavelengths, at least across the visible portion of the spectrum, so that the product, the combination of the medium with the nanophosphors, is color-neutral.

For example, the material or medium, i.e. gas or liquid, used to bear the nanophosphors may be at least substantially clear or transparent. Translucent materials are also contemplated. To optimize performance, the material will have a low absorptivity with respect to the relevant wavelengths, particularly those in the visible portion of the spectrum as emitted by the nanophosphor(s). To avoid any perceptible tint, the absorptivity of the material will also be relatively wavelength independent across at least that visible portion of the spectrum. For example, the overall appearance of a transparent material with the nanophosphor(s) contained therein would be relatively clear, when the device (and thus the semiconductor) is off.

Reference now is made in detail to the examples illustrated in the accompanying drawings and discussed below. FIGS. 1A-1B illustrate visible white light type LED devices, in cross section, by way examples 11a, 11b of solid state light emitting devices of the type discussed herein. The structural configuration of the solid state light emitting devices 11a, 11b shown in FIGS. 1A and 1B are presented here by way of examples only. Those skilled in the art will appreciate that the device may utilize any device structure.

In the examples, the solid state light emitting devices 11a, 11b include a semiconductor chip, comprising two or more semiconductor layers 13, 15 forming the actual LED. In our first example, the semiconductor layers 13, 15 of the chip are mounted on an internal reflective cup 17, formed as an extension of a first electrode, e.g. the cathode 19. The cathode 19 and an anode 21 provide electrical connections to layers of the semiconductor chip within the packaging for the devices 11a, 11b. When appropriate current is supplied through the cathode 19 and the anode 21 to the LED chip layers 15 and 13, the chip emits electromagnetic energy. In the example, a dome 23 (or similar transmissive part) of the enclosure allows for emission of the electromagnetic energy from the devices 11a, 11b in the desired direction.

The chip structure shown is given by way of a simple example, only. Those skilled in the art will appreciate that the devices 11a, 11b can utilize any semiconductor chip structure, where the chip is configured as a source of 380-420 nm near UV range electromagnetic energy, for example, having substantial energy emissions in that range such as a predominant peak at or about 405 nm. The simplified example shows a LED type semiconductor chip formed of two layers 13, 15. Those skilled in the art will recognize that actual chips may have a different number of device layers.

In certain specific examples, the LED type semiconductor chip is constructed so as to emit electromagnetic energy of a wavelength in the near UV range, in this case in the 380-420 nm range. By way of a specific example, we will assume that the layers 13, 15 of the LED chip are configured so that the LED emits electromagnetic energy with a main emission peak at 405 nm.

Semiconductor devices such as the light emitting device formed by layers 13, 15 exhibit emission spectra having a relatively narrow peak at a predominant wavelength, although some such devices may have a number of peaks in their emission spectra. Such devices may be rated with respect to the intended wavelength of the predominant peak, although there is some variation or tolerance around the rated value, from chip to chip due to manufacturing tolerances. The semiconductor chip in the solid state light emitting devices 11a, 11b will have a predominant wavelength (λ) at or below 460 nm (λ≦460 nm). For example, the chips in the examples of FIGS. 1A and 1B is rated for a 405 nm output, which means that it has a predominant peak in its emission spectra at or about 405 nm (within the manufacturer's tolerance range of that rated wavelength value) in the 380-420 nm near UV range. Examples of devices 11a, 11b, however, may use chips that have additional peaks in their emission spectra.

Each of solid state light emitting devices 11a, 11b also includes a housing 25. The housing and the light transmissive dome 23 together form the package enclosing the LED chip, in this example. Typically, the housing 25 is metal, e.g. to provide good heat conductivity so as to facilitate dissipation of heat generated during operation of the LED. Internal reflectors, such as the reflective cup 17, direct energy in the desired direction and reduce internal losses.

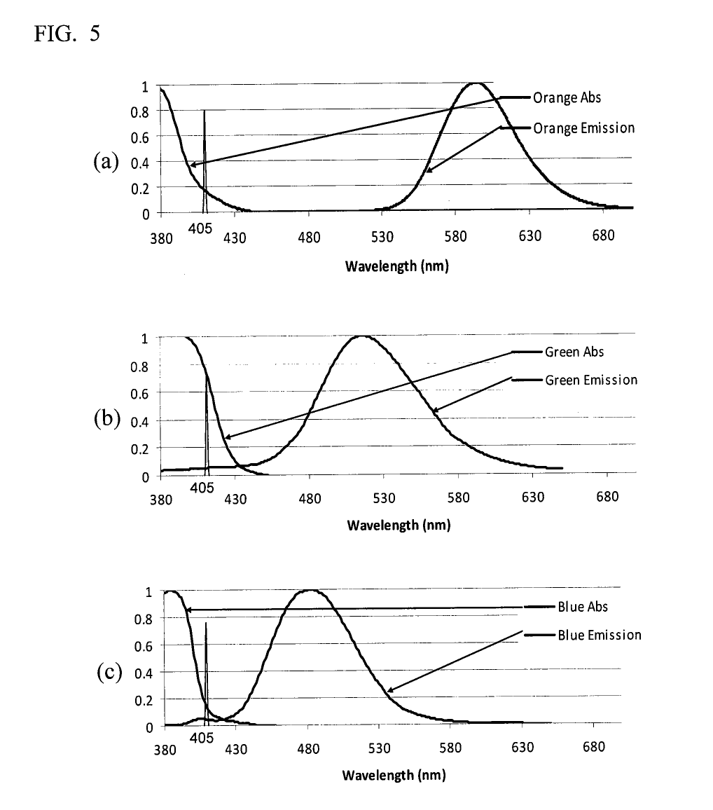

Each of the solid state light emitting devices 11a, 11b also incorporates an appropriately formulated nanophosphor material within the device package itself, to enable the respective device 11a or 11b to produce the desired white light. The nanophosphor material includes a number of different types of doped or non-doped semiconductor nanophosphors. The semiconductor nanophosphors are all excited, however, the emission spectra of the different semiconductor nanophosphors are different. Each type of nanophosphors re-emits visible light of a different spectral characteristic; and at least in examples using doped semiconductor nano-phosphors, each of the phosphor emission spectra has little or no overlap with excitation or absorption ranges of the nanophosphors. Particular semiconductor nanophosphors are chosen and mixed in proportions, in the specific examples, so that the resultant combined light output through the exposed surface of the dome 23 is white light having a CRI of 75 or higher and having a color temperature in a specific one of the four ranges recited above. Specific combinations of emission spectra of appropriate semiconductor nanophosphors will be discussed in more detail, later, with regard to FIGS. 5-7.

The semiconductor nanophosphors could be at various locations and formed in various ways within the package of the solid state light emitting devices 11a, 11b. In the illustrated examples, the mix of semiconductor nanophosphors is located across the optical output of the solid state light emitting devices 11a, 11b. The nanophosphors, for example, are contained within the dome 23 and the dome 23 also serves as a container or housing for the nanophosphors. In FIG. 1A, the dome 23 contains a transmissive material, in this example a gas (G) 27a, bearing the nanophosphor(s), which at least substantially fills the interior volume of the dome 23. The gas should not include oxygen as oxygen tends to degrade the nanophosphors. In the example shown in FIG. 1A, the dome 23 forms a container for housing at least one doped semiconductor nanophosphor contained in a gas. In the example shown in FIG. 1B, the dome 23 forms a container for housing at least one doped semiconductor nanophosphor contained in a liquid (L) 27b.

The transmissive liquid (27b) or gaseous (27a) material preferably exhibits high transmissivity and/or low absorption to light of the relevant wavelengths. The material may be a liquid (L), shown in FIG. 1B or a gas (G), shown in FIG. 1A, to help to improve the florescent emissions by the nanophosphors in the material. For example, alcohol, oils (synthetic, vegetable, silicon or other oils) or other liquid media may be used. A silicone material, epoxy or glass may be used along the exterior of the dome to form a container, either of which can provide an oxygen barrier to reduce nanophosphor degradation due to exposure to oxygen. Any of a number of various sealing arrangements may be used to seal the interior of the dome container 23 once filled, so as to maintain a good oxygen barrier and thereby shield the semiconductor nanophosphors from oxygen. Thus, the dome serves as a container for the liquid or gas material.

In an example where the bearer material for the phosphor(s) is liquid, a bubble may be created when the container is filled. If present, the bubble may be either a gas-filled bubble or a vacuum-vapor bubble. If the bubble contains a deliberately provided gas, that gas should not contain oxygen or any other element that might interact with the nanophosphor. Nitrogen would be one appropriate example of a gas that may be used.

If the bubble is a vacuum-vapor bubble, the bubble is formed by drawing a vacuum, for example, due to the properties of the suspension or environmental reasons. If a gas is not deliberately provided, vapors from the liquid will almost certainly be present within the vacuum, whenever conditions would create some vacuum pressure within the container. For example, the vacuum-vapor bubble might form due to a vacuum caused by a differential between a volume of the liquid that is less than the volume of the interior of the container. This might occur for example due to a low temperature of the liquid, for example, if the liquid is placed in the container while hot and allowed to cool or if the liquid is of such an amount as to precisely fill the container at a designated operating temperature but the actual temperature is below the operating temperature. Any vapor present would be caused by conversion of the liquid to a gas under the reduced pressure.

In either case, the gas bubble or the vacuum-vapor bubble can be sized to essentially disappear when the suspension material reaches its nominal operating temperature, with sizing such that the maximum operating pressure is not exceeded at maximum operating temperature. If it is a gas-filled bubble, it will get smaller, but will probably not completely disappear with increased temperature. The preferred embodiment is a vacuum-vapor bubble, which may disappear completely at appropriate temperatures.

If a gas is used, the gaseous material, for example, may be hydrogen or nitrogen gas, any of the inert gases, and possibly some hydrocarbon based gases. Combinations of one or more such types of gases might be used.

The material is transmissive and has one or more properties that are wavelength independent. A clear material used to bear the nanophosphors would have a low absorptivity with little or no variation relative to wavelengths, at least over most if not all of the visible portion of the spectrum. If the material is translucent, its scattering effect due to refraction and/or reflection will have little or no variation as a function of wavelength over at least a substantial portion of the visible light spectrum.

In the examples shown in FIGS. 1A and 1B, phosphors can additionally be present as a coating over the outside of the domed container 23, or the phosphor particles could be doped or otherwise embedded in a portion or all of the material forming the outer perimeter of the domed container 23 itself. The phosphors could also be part of or coated on a reflective material of the cup 17. At least some semiconductor nanophosphors degrade in the presence of oxygen, reducing the useful life of the nanophosphors. Hence, it may be desirable to use materials and construct the devices 11a, 11b so as to effectively encapsulate the semiconductor nanophosphors 27 in a manner that blocks out oxygen, to prolong useful life of the phosphors.

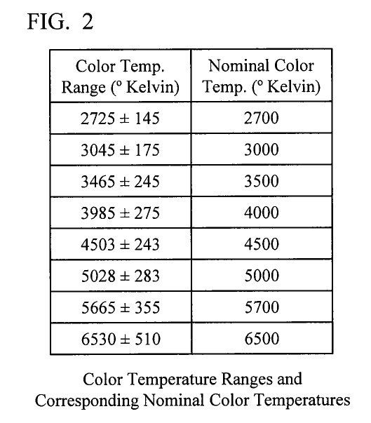

When the phosphors 27 are pumped by energy from the LED chip, the combined light output of either of the solid state light emitting devices 11a, 11b is at least substantially white and has a color rendering index (CRI) of 75 or higher. As shown in the table in FIG. 2, the white output light of the devices 11a, 11b exhibit color temperature in one of the following specific ranges along the black body curve: 2,725±145° Kelvin; 3,045±175° Kelvin; 3,465±245° Kelvin; 3,985±275° Kelvin; 4,503±243° Kelvin; 5,028±283° Kelvin; 5,665±355° Kelvin; and 6,530±510° Kelvin. These ranges correspond to nominal color temperature values shown in the table. The nominal color temperature values represent the rated or advertised color temperatures as would apply to particular lighting fixture or system products having an output color temperature within the corresponding ranges.

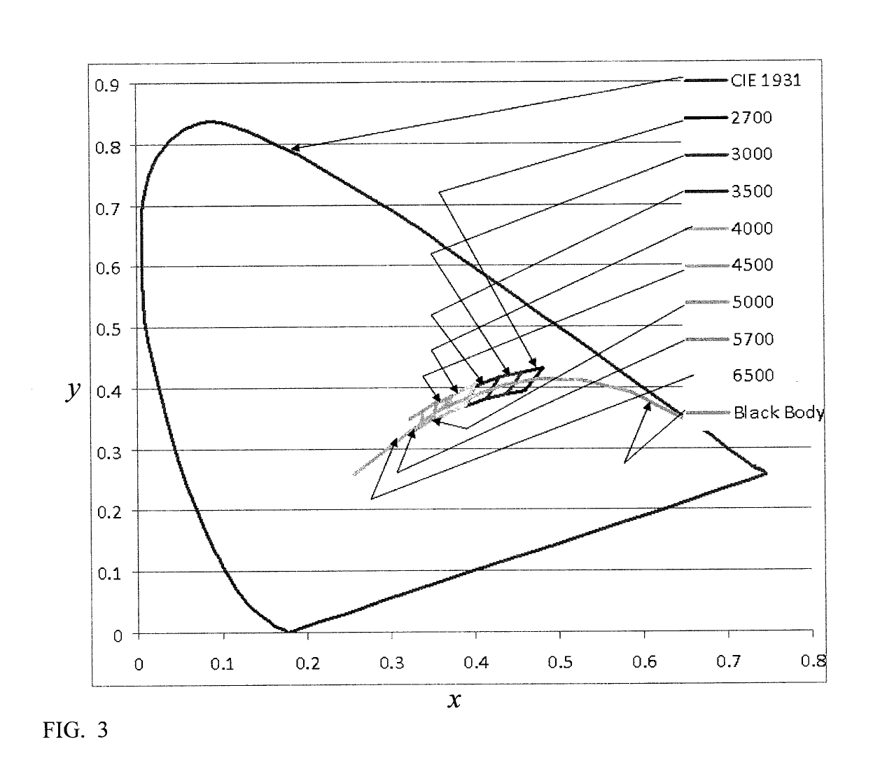

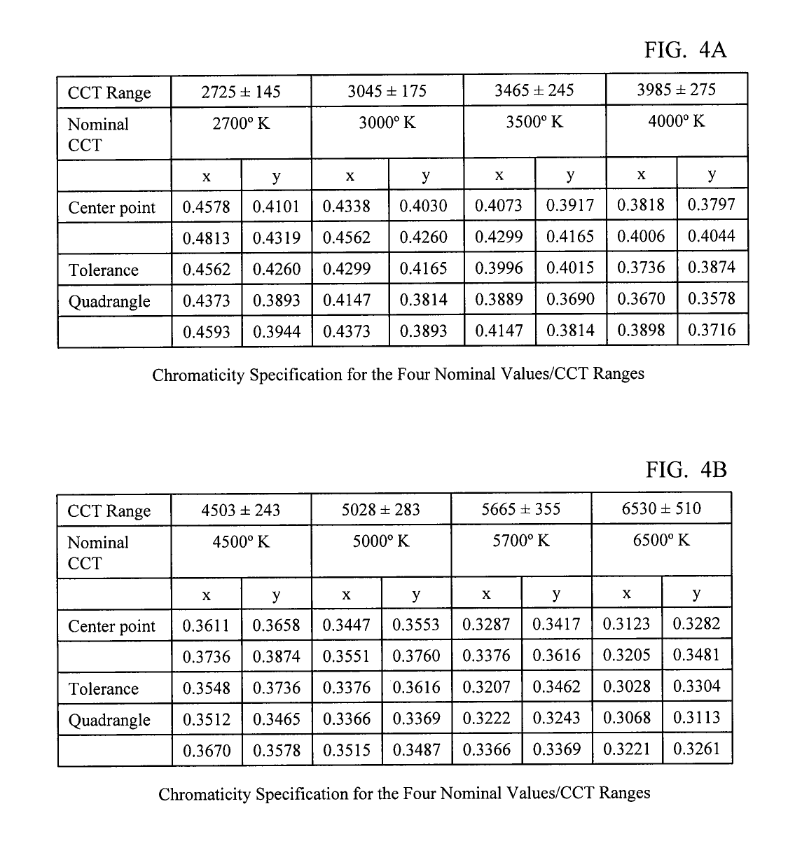

The color temperature ranges fall along the black body curve. FIG. 3 shows the outline of the CIE 1931 color chart, and the curve across a portion of the chart represents a section of the black body curve that includes the desired CIE color temperature (CCT) ranges. The light may also vary somewhat in terms of chromaticity from the coordinates on the black body curve. The quadrangles shown in the drawing represent the range of chromaticity for each nominal CCT value. Each quadrangle is defined by the range of CCT and the distance from the black body curve. The table in FIG. 4A provides a chromaticity specification for each of the first four color temperature ranges. The table in FIG. 4B provides a chromaticity specification for each of the other four color temperature ranges. The x, y coordinates define the center points on the black body curve and the vertices of the tolerance quadrangles diagrammatically illustrated in the color chart of FIG. 3.

The solid state light emitting devices 11a, 11b could use a variety of different combinations of semiconductor nanophosphors. Examples of suitable doped semiconductor nanophosphor materials are available from NN Labs of Fayetteville, Ark. In a specific example, one or more of the doped semiconductor nanophosphors comprise zinc selenide quantum dots doped with manganese or copper. The selection of one or more such nanophosphors of the visible spectrum and/or by UV energy together with dispersion of the nanophosphors in an otherwise color-neutral material, in this example, a clear or translucent gas or liquid, minimizes any potential for discolorization in the off-state that might otherwise be caused by the presence of a phosphor material.

Doped semiconductor nanophosphors exhibit a large Stokes shift, that is to say from a short-wavelength range of absorbed energy up to a fairly well separated longer-wavelength range of emitted light. FIG. 5 shows the absorption and emission spectra of three examples of doped semiconductor nanophosphors. For purposes of discussion, a specific example we will assume use o a LED chip configured to emit a rated light output at or around 405 nm. For that example, each line of the graph also includes an approximation of the emission spectra of the 405 nm LED chip, to help illustrate the relationship of the 405 nm LED emissions to the absorption spectra of the exemplary doped semiconductor nanophosphors. The illustrated spectra are not drawn precisely to scale, but in a manner to provide a teaching example to illustrate our discussion here.

The top line (a) of the graph shows the absorption and emission spectra for an orange emitting doped semiconductor nanophosphor. The absorption spectrum for this first phosphor includes the 380-420 nm near UV range and extends down into the UV range, but that absorption spectrum drops substantially to 0 before reaching 450 nm. As noted, the phosphor exhibits a large Stokes shift from the short wavelength(s) of absorbed light to the longer wavelengths of re-emitted light. The emission spectrum of this first phosphor has a fairly broad peak in the wavelength region humans perceive as orange. Of note, the emission spectrum of this first phosphor is well above the illustrated absorption spectra of the other doped semiconductor nanophosphors and well above its own absorption spectrum. As a result, orange emissions from the first doped semiconductor nanophosphor would not re-excite that phosphor and would not excite the other doped semiconductor nanophosphors if mixed together. Stated another way, the orange phosphor emissions would be subject to little or no phosphor re-absorption, even in mixtures containing one or more of the other doped semiconductor nanophosphors.

The next line (b) of the graph of FIG. 5 shows the absorption and emission spectra for a green emitting doped nanocrystal doped semiconductor nanophosphor. The absorption spectrum for this second phosphor includes the 380-420 nm near UV range and extends down into the UV range, but that absorption spectrum drops substantially to 0 a little below 450 nm. This phosphor also exhibits a large Stokes shift from the short wavelength(s) of absorbed light to the longer wavelengths of re-emitted light. The emission spectrum of this second phosphor has a broad peak in the wavelength region humans perceive as green. Again, the emission spectrum of the phosphor is well above the illustrated absorption spectra of the other doped semiconductor nanophosphors and well above its own absorption spectrum. As a result, green emissions from the second doped semiconductor nanophosphor would not re-excite that phosphor and would not excite the other doped semiconductor nanophosphors if mixed together. Stated another way, the green phosphor emissions also should be subject to little or no phosphor re-absorption, even in mixtures containing one or more of the other doped semiconductor nanophosphors.

The bottom line (c) of the graph of FIG. 5 shows the absorption and emission spectra for a blue emitting doped semiconductor nanophosphor. The absorption spectrum for this third phosphor includes the 380-420 nm near UV range and extends down into the UV range, but that absorption spectrum drops substantially to 0 between 400 and 450 nm. This phosphor also exhibits a large Stokes shift from the short wavelength(s) of absorbed light to the longer wavelengths of re-emitted light. The emission spectrum of this third phosphor has a broad peak in the wavelength region humans perceive as blue. The main peak of the emission spectrum of the phosphor is well above the illustrated absorption spectra of the other doped semiconductor nanophosphors and well above its own absorption spectrum. In the case of the blue example, there is just a small amount of emissions in the region of the phosphor absorption spectra. As a result, blue emissions from the third doped semiconductor nanophosphor would not re-excite that phosphor and the other doped semiconductor nanophosphors at most a minimal amount. As in the other phosphor examples of FIG. 5, the blue phosphor emissions would be subject to relatively little phosphor re-absorption, even in mixtures containing one or more of the other doped semiconductor nanophosphors.

Examples of suitable orange, green and blue emitting doped semiconductor nanophosphors of the types generally described above relative to FIG. 5 are available from NN Labs of Fayetteville, Ark.

As explained above, the large Stokes shift results in negligible re-absorption of the visible light emitted by doped semiconductor nanophosphors. This allows the stacking of multiple phosphors. It becomes practical to select and mix two, three or more such phosphors in a manner that produces a particular desired spectral characteristic in the combined light output generated by the phosphor emissions.

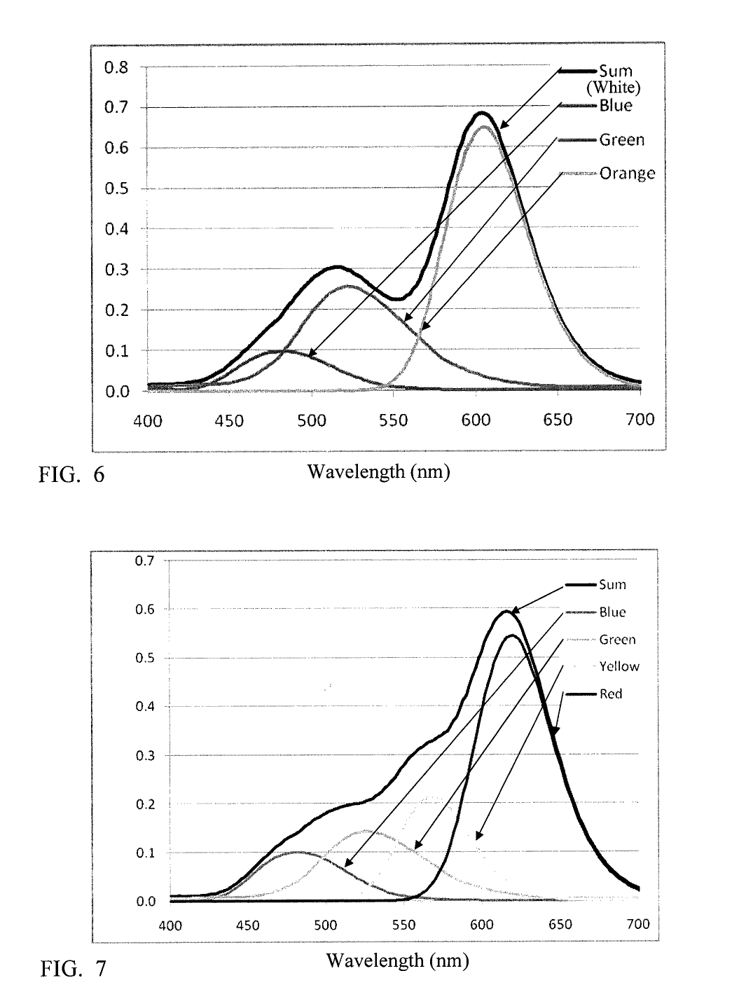

FIG. 6 graphically depicts emission spectra of three of the doped semiconductor nanophosphors selected for use in an exemplary solid state light emitting device as well as the spectrum of the white light produced by summing or combining proportional amounts of spectral emissions from those three phosphors. For convenience, the emission spectrum of the LED has been omitted from FIG. 6, on the assumption that a high percentage of the 405 nm light from the LED is absorbed by the phosphors. Although the actual output emissions from the device 11 may include some near UV light from the LED chip, the contribution thereof if any to the sum in the output spectrum should be relatively small.

Although other combinations are possible based on the phosphors discussed above relative to FIG. 5 or based on other semiconductor nanocrystal phosphors, the example of FIG. 6 represents emissions of blue, green and orange phosphors. The emission spectra of the blue, green and orange emitting doped semiconductor nanophosphors are similar to those of the corresponding color emissions shown in FIG. 5. Light is additive. The amount of each phosphor emission spectra in the device output depends on the relative amount of the particular phosphor contained in the mixture used in the solid state device. The heights of the respective color emission spectra (FIG. 6) relate to the proportional amounts of the phosphors in the mixture. Where the solid state light emitting devices 11a, 11b include the respective amounts of blue, green and orange emitting doped semiconductor nanophosphors as shown for example at 27 in FIGS. 1A and 1B, the addition of the blue, green and orange emissions produce a combined spectrum as approximated by the top or ‘Sum’ curve in the graph of FIG. 6.

It is possible to add one or more additional nanophosphors, e.g. a fourth, fifth, etc., to the mixture to further improve the CRI. For example, to improve the CRI of the nanophosphor mix of FIGS. 5 and 6, a doped semiconductor nanophosphor might be added to the mix with a broad emissions spectrum that is yellowish-green or greenish-yellow, that is to say with a peak of the phosphor emissions somewhere in the range of 540-570 nm, say at 555 nm.

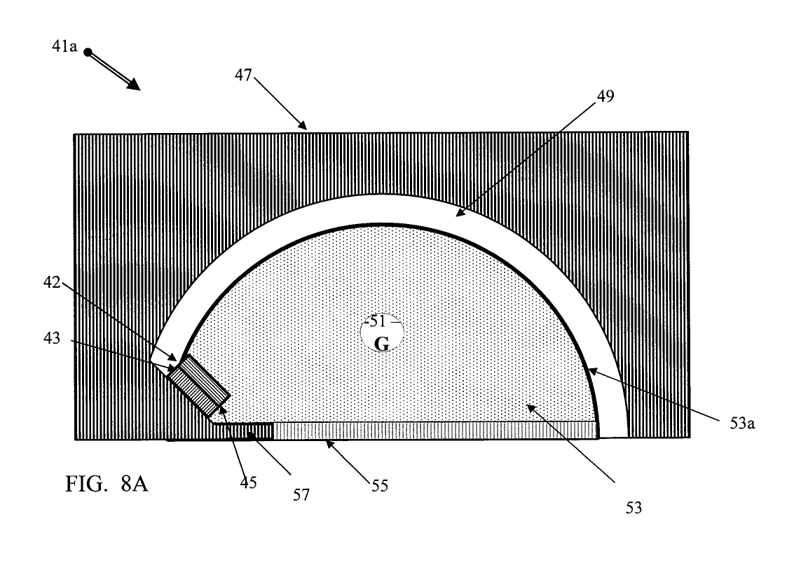

Other mixtures also are possible, with two, three or more doped semiconductor nanophosphors and/or one or more non-doped semiconductor nanophosphors. The example of FIG. 7 uses red, green and blue emitting doped semiconductor nanophosphors, as well as a yellow fourth doped semiconductor nanophosphor. Although not shown, the absorption spectra would be similar to those of the three nanophosphors discussed above relative to FIG. 5. For example, each absorption spectrum would include at least a portion of the 380-420 nm near UV range. All four phosphors would exhibit a large Stokes shift from the short wavelength(s) of absorbed light to the longer wavelengths of re-emitted light, and thus their emissions spectra have little or not overlap with the absorption spectra.

In this example (FIG. 7), the blue nanophosphor exhibits an emission peak at or around 484, nm, the green nanophosphor exhibits an emission peak at or around 516 nm, the yellow nanophosphor exhibits an emission peak at or around 580, and the red nanophosphor exhibits an emission peak at or around 610 nm. The addition of these blue, green, red and yellow phosphor emissions produces a combined spectrum as approximated by the top or ‘Sum’ curve in the graph of FIG. 7. The ‘Sum’ curve in the graph represents a resultant white light output having a color temperature of 2600° Kelvin (within the 2,725±145° Kelvin range), where that white output light also would have a CRI of 88 (higher than 75).

Various mixtures of semiconductor nanophosphors will produce white light emissions from solid state light emitting devices 11a, 11b that exhibit CRI of 75 or higher. For an intended device specification, a particular mixture of phosphors is chosen so that the light output of the device exhibits color temperature in one of the following specific ranges along the black body curve: 2,725±145° Kelvin; 3,045±175° Kelvin; 3,465±245° Kelvin; 3,985±275° Kelvin; 4,503±243° Kelvin; 5,028±283° Kelvin; 5,665±355° Kelvin; and 6,530±510° Kelvin. In the example shown in FIG. 6, the ‘Sum’ curve in the graph produced by the mixture of blue, green and orange emitting doped semiconductor nanophosphors would result in a white light output having a color temperature of 2800° Kelvin (within the 2,725±145° Kelvin). That white output light also would have a CRI of 80 (higher than 75).

Returning to FIGS. 1A, 1B, assume that the phosphors 27a, 27b in the devices 11a, 11b include the blue, green and orange emitting doped semiconductor nanophosphors discussed above relative to FIGS. 2 and 3. As discussed earlier, the semiconductor LED chip formed by layers 13 and 15 is rated to emit near UV electromagnetic energy of a wavelength in the range at or below 460 nm (λ≦460 nm), such as 405 nm in the illustrated example, which is within the excitation spectrum of each of the three included phosphors in the mixture shown at 27a or 27b. When excited, that combination of doped semiconductor nanophosphors re-emits the various wavelengths of visible light represented by the blue, green and orange lines in the graph of FIG. 6. Combination or addition thereof in the device output produces “white” light, which for purposes of our discussion herein is light that is at least substantially white light. The white light emissions from the solid state light emitting devices 11a, 11b exhibit a CRI of 75 or higher (80 in the specific example of FIG. 6). Also, the light outputs of the devices 11a, 11b exhibit color temperature of 2800° Kelvin, that is to say within the 2,725±145° Kelvin range. Other combinations of doped semiconductor nanophosphors can be used in devices 11a, 11b to produce the high CRI white light in the 3,045±175° Kelvin, 3,465±245° Kelvin, 3,985±275° Kelvin, 4,503±243° Kelvin, 5,028±283° Kelvin, 5,665±355° Kelvin, and 6,530±510° Kelvin ranges.

Hence, the solid state light emitting devices 11a, 11b are white light type devices, even though internally the semiconductor chip is a 405 nm LED in the most specific examples. The light outputs of the solid state light emitting devices 11a, 11b are high quality white light suitable for general lighting applications and the like. Of course, the white light from the sources 11a, 11b may be used in many other applications. Depending on the particular application, the white light solid state light emitting devices 11a, 11b may be used directly as a white light source, or the devices 11a, 11b can be combined with an appropriate external optic (reflector, diffuser, lens, prism, etc., not shown) to form a light fixture or the like.

The structure of the solid state light emitting devices shown in FIGS. 1A, 1B are given by way of example only. Those skilled in the art will recognize that the semiconductor chip and the semiconductor nanophosphors may be implemented in any of a wide range of device designs, including many structures known for LED type devices that have previously incorporated semiconductor nanophosphors or other types of phosphors. A particularly advantageous approach to the device design, however, would include at least one diffusely reflective surface within the package forming an optical integrating cavity. The semiconductor chip would be positioned and oriented so that at least substantially all direct emissions from the semiconductor chip reflect at least once within the cavity. Emissions from the doped semiconductor nanophosphors within the device also would be reflected and integrated within the cavity.

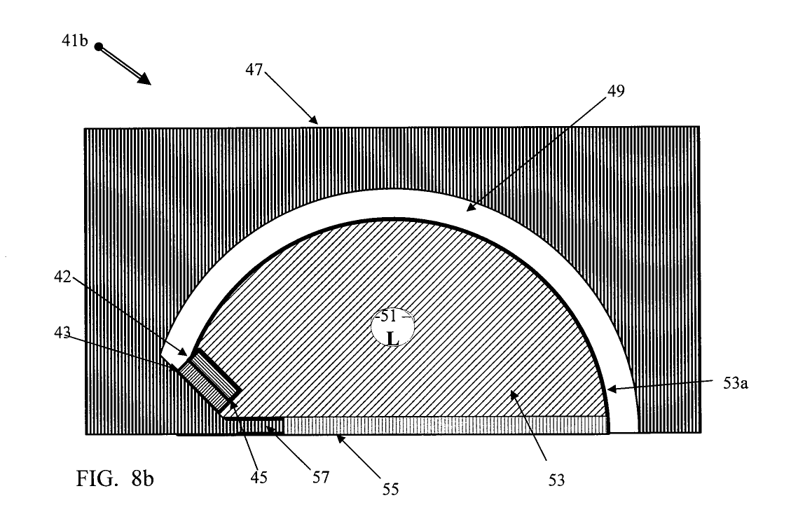

To fully appreciate this further enhancement and its advantages, it may be helpful to discuss simplified examples, such as represented in cross-section in FIGS. 8A and 8B. In the examples, the solid state light emitting devices 41a, 41b includes a semiconductor chip 42, comprising by way of a simple example the two semiconductor layers 43, 45. The two or more semiconductor layers form the actual emitter, in this case a LED. The chip 42 is similar to that formed by the exemplary layers 13 and 15 in the devices 11a, 11b of FIGS. 1A, 1B. A single chip 42 is shown for simplicity, although the devices 41a, 41b could include one or more additional semiconductor chips. By way of the most specific example, we will assume that the layers of the LED chip 42 are configured so that the LED emits electromagnetic energy with a main emission peak at 405 nm.

The semiconductor chip 42 is mounted on an internal reflective cup, in this case formed by a region of the metal housing member 47 (including a mask 57, as discussed more later). The metal housing 47 also dissipates heat generated by the chip 42 during its operation. In this example, we have assumed that the metal housing (heat slug) 47 of the solid state white light emitter devices 41a, 41b is conductive and provides the connection lead to the layer 43, otherwise, connection leads to various layers of the chip have been omitted, for ease of illustration and discussion. Of course, a variety of other configurations for mounting the chip and providing electrical connections and heat dissipation may be used.

In this example, the orientation of the chip relative to the optical output of the devices 41a, 41b is quite different from that of the devices 11a, 11b of FIGS. 1A, 1B. The configuration of the devices in FIGS. 1A, 1B aims the emissions from the chip toward the optical output of the devices 11a, 11b as much as possible and minimizes reflections within the device. The structure of the device devices 41a, 41b positions and orients the chip so that direct emissions through the optical output are minimal or eliminated and light directly emitted from the chip excites phosphors and/or reflects one or more times within the device.

The chip housing member 47 is configured to form a volume, and there is a reflector 49 at the surface of the member 47 forming that volume. The reflector 49 may be formed in a number of different ways, for example, by polishing and/or etching the surface, or by coating the surface with an appropriately reflective material. Preferably, the reflector 49 is diffusely reflective with respect to the wavelengths involved in operation of the device 41. The reflector 49 forms a reflective volume within the device 41 forming an optical cavity 51.

The cavity 51 may have various shapes. Examples having shapes corresponding to a portion or segment of a sphere or cylinder are preferred for ease of illustration and/or because curved surfaces provide better efficiencies than other shapes that include more edges and corners which tend to trap light. Those skilled in the art will understand, however, that the volume of the cavity of the device 41 may have any shape providing adequate reflections within the volume/cavity 51 for a particular lighting application.

For purposes of further discussion, we will assume that the material forming the reflector 49 is diffusely reflective. It is desirable that the cavity surface or surfaces have a highly efficient reflective characteristic, e.g. a reflectivity equal to or greater than 90%, e.g. approximately 97-99% reflective, with respect to energy in at least the visible and near-ultraviolet portions of the electromagnetic spectrum.

In the solid state light emitting devices 41a, 41b, the volume of the optical integrating cavity 51 is substantially filled with the light transmissive material 53, namely a liquid (L), as shown in FIG. 8B, or gaseous (G) material, as shown in FIG. 8A. A containment member 53a is configured to contain the light transmissive material 53 such that the light transmissive material 53 fills at least a substantial portion of the optical integrating cavity 51. The chip housing member 47 and the light transmissive material 53 together form the package enclosing the LED chip 42 and the reflector 49, in this example. The light transmissive material 53 may be transparent or somewhat diffuse (milky or translucent).

The light transmissive liquid or gaseous material 53 is housed within containment member 53a such that the containment member has a contoured outer surface that closely conforms to the inner surface of the reflector 49. The optical cavity 51 also has a solid optical aperture surface 55. Although there may be other elements forming the optic of the devices 41a, 41b, in the example, the surface 55 which forms an optical aperture for passage of light out of the cavity 51 also serves as the optical output of the solid state light emitting devices 41a, 41b. The surface 55 may be convex or concave, or have other contours, but in the example, the surface 55 is flat.

The optical aperture 55 in this example approximates a circle, although other shapes are possible. One or more additional elements (not shown) may be provided at or coupled to the aperture 55, such as a deflector, diffuser or filter. If a filter is provided, for example, the filter at the aperture 55 might allow passage of visible light but block any UV emissions from the cavity 51. The optical aperture surface may be transparent, or that surface may have a somewhat roughened or etched texture.

The semiconductor chip 42 is positioned and oriented relative to the light transmissive material 53 so that any electromagnetic energy reaching the aperture 55 directly from the chip 42 impacts the surface 55 at a sufficiently small angle as to be reflected back into the optical integrating cavity 51 by total internal reflection.

Although it may not be necessary in all implementations, depending on the precise location and orientation, the exemplary devices 41a, 41b also include a mask 57 having a reflective surface facing into the optical integrating cavity 51, which somewhat reduces the area of the surface forming output passage (optical aperture) shown at 55. As noted, the surface of the mask 57 that faces into the optical integrating volume 51 (faces upward in the illustrated orientation) is reflective. That surface may be diffusely reflective, much like the surface of the reflector 49, or that mask surface may be specular, quasi specular or semi-specular.

Due to the total internal reflection of the solid surface forming the optical aperture 55, the mask 57 can be relatively small in that it only needs to extend far enough out so as to block direct view of the chip 42 through the aperture 55 and to reflect those few direct emissions that might otherwise still impact the aperture 55 at too high or large an angle for total internal reflection. In this way, the combination of total internal reflection of the surface of aperture 55 together with the reflective mask 57 reflects all or at least substantially all of the direct emissions from the chip 42, that otherwise would miss the surface of the reflector 49, back into the optical integrating volume 51. Stated another way, a person viewing the devices 41a, 41b during operation would not visibly perceive the chip 42. Instead, virtually all energy input to the volume of the cavity 51 from the semiconductor chip 42 will diffusely reflect one or more times from the surface of the reflector 49 before emergence through the aperture 55. Since the surface of the reflector 49 provides diffuse reflectivity, the volume 51 acts as an optical integrating cavity so that the surface of aperture 55 forms an optical aperture providing a substantially uniform virtual source output distribution of integrated light (e.g. substantially Lambertian) across the area of the surface of aperture 55.

To this point we have focused on the structure and optical aspects of the solid state light emitting devices 41a, 41b. However, like the devices 11a, 11b in the earlier examples, the devices 41a, 41b include phosphors, such as semiconductor nanophosphors, for converting the energy from the chip 42 into visible white light, with a color rendering index (CRI) of 75 or higher. By using one of the mixtures of semiconductor nanophosphors, like those in certain of the earlier examples, the white output light may exhibit a color temperature in one of the several specific ranges along the black body curve. Again, it may be desirable to use materials and construct the devices 11a, 11b so as to effectively contain or house the semiconductor nanophosphors in a manner that blocks out oxygen, to prolong useful life of the phosphors.

In the examples of FIGS. 8A, 8B, it is assumed that the solid state light emitting devices 41a, 41b include semiconductor nanophosphors that or otherwise dispersed in the light transmissive material 53 and contained within containment member 53a. The containment member 53a as described herein can be a fully enclosed container separate from and in addition to the optical integrating cavity 51, as well as a plate or other element at the aperture 55 to close off the cavity 51 so that the cavity 51 itself becomes the container. Again, the light transmissive material includes a liquid or gaseous material for dispersing the phosphors. The phosphors may be fairly widely dispersed throughout the material 53 to minimize visible discoloration caused by the phosphors when the device is off.

The semiconductor nanophosphors could also be doped or otherwise embedded in the material of the reflector 49. Alternatively, the phosphors could be applied as a coating between the surface of the reflector 49 and the matching contoured surface of the light transmissive material 53. Another approach might be to place the phosphors on or around the semiconductor chip 42. Yet another approach might be to coat the doped semiconductor nanophosphors on the surface 55, although that would not take the best advantage of the integrating property of the cavity 51.

In the examples of FIGS. 8A, 8B, the semiconductor chip 42 emits energy mostly toward the inner surface of reflector 49. Electromagnetic energy emitted from the chip 42 in other directions is reflected by the inner surface of the mask 57 or total internal reflection at the surface of optical aperture 55 towards the inner surface of reflector 49. As the energy from the chip 42 and from the mask 57 and the surface 55 passes through the light transmissive material 53, it excites the semiconductor nanophosphors dispersed in the light transmissive material 53 (e.g. gas or liquid) housed in containment member 53a. The containment member 53a as described herein can be a fully enclosed container separate from and in addition to the optical integrating cavity 51, as well as a plate or other element at the aperture 55 to close off the cavity 51 so that the cavity 51 itself becomes the container. Any energy that has not yet excited a phosphor reflects from the diffusely reflective surface of the reflector 49 back through the transmissive material 53 and may excite the semiconductor nanophosphors in the light transmissive material 53 on the second or subsequent pass. Light produced by the phosphor excitations, is emitted in all directions within the cavity 51. Much of that light is also reflected one or more times from the inner surface of reflector 49, the inner surface of the mask 57 and the total internal reflection at the surface of aperture 55. At least some of those reflections, particularly those off the inner surface of reflector 49, are diffuse reflections. In this way, the cavity 51 integrates the light produced by the various phosphor emissions into a highly integrated light for output via the surface of optical aperture 55 (when reaching the surface at a steep enough angle to overcome the total internal reflection).

This optical integration by diffuse reflection within the cavity 51 integrates the light produced by the nano-phosphor excitation to form integrated light of the desired characteristics at the optical aperture 55 providing a substantially uniform output distribution of integrated light (e.g. substantially Lambertian) across the area of the aperture. As in the earlier examples, the particular semiconductor nanophosphors in the devices 41a, 41b result in a light output that is at least substantially white and has a color rendering index (CRI) of 75 or higher. The white light output of the solid state light emitting devices 41a, 41b through optical aperture 55 exhibits color temperature in one of the specified ranges along the black body curve. The semiconductor nanophosphors may be selected and mixed to stack the emissions spectra thereof so that the white light output through optical aperture 55 exhibits color temperature of 2,725±145° Kelvin. Alternatively, the semiconductor nanophosphors may be selected and mixed to stack the emissions spectra thereof so that the white light output through optical aperture 55 exhibits color temperature of 3,045±175° Kelvin. As yet another alternative, the semiconductor nanophosphors may be selected and mixed to stack the emissions spectra thereof so that the white light output through optical aperture 55 exhibits color temperature of 3,465±245° Kelvin. As a further alternative, the semiconductor nanophosphors may be selected and mixed to stack the emissions spectra thereof so that the white light output through optical aperture 55 exhibits color temperature of and 3,985±275° Kelvin. The semiconductor nanophosphors may be selected and mixed to stack the emissions spectra thereof so that the white light output through optical aperture 55 exhibits color temperature of 4,503±243° Kelvin; or the semiconductor nanophosphors may be selected and mixed to stack the emissions spectra thereof so that the white light output through optical aperture 55 exhibits color temperature of 5,028±283° Kelvin. As yet further alternatives, the semiconductor nanophosphors may be selected and mixed to stack the emissions spectra thereof so that the white light output through optical aperture 55 exhibits color temperature of 5,665±355° Kelvin; or the semiconductor nanophosphors may be selected and mixed to stack the emissions spectra thereof so that the white light output through optical aperture 55 exhibits color temperature of 6,530±510° Kelvin.

The effective optical aperture at 55 forms a virtual source of white light from the solid state light emitting devices 41a, 41b. The integration tends to form a relatively Lambertian distribution across the virtual source, in this case, the full area of the optical aperture at surface 55. Depending of design constraints of the device manufacture/market place, the aperture area may be relatively wide without exposing the chip as an intense visible point source within the device. When the device is observed in operation, the virtual source at 55 appears to have substantially infinite depth of the integrated light. The optical integration sufficiently mixes the light so that the light output exhibits a relatively low maximum-to-minimum intensity ratio across that optical aperture 55. In virtual source examples discussed herein, the virtual source light output exhibits a maximum-to-minimum ratio of 2 to 1 or less over substantially the entire optical output area.

Nano-phosphors, including doped and/or non-doped semiconductor nanophosphors used herein, produce relatively uniform repeatable emission spectra. Thus, having chosen an appropriate phosphor mixture to produce light of the desired CRI and color temperature, the solid state light emitting devices using that nano-phosphor may consistently produce white light having the CRI in the same range and color temperature in the same range with less humanly perceptible variation between devices as has been experienced with prior LED devices and the like.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A solid state light emitting device, comprising:
a semiconductor chip for producing electromagnetic energy;
a package enclosing the semiconductor chip and configured to allow emission of light as an output of the device; and
a plurality of semiconductor nanophosphors dispersed in a light transmissive liquid or gas contained within the package, each of the semiconductor nanophosphors having a respective absorption spectrum encompassing an emission spectrum of the semiconductor chip for re-emitting visible light of a different spectrum, for together producing visible light in the output of the device when the semiconductor nanophosphors are excited by electromagnetic energy from the semiconductor chip,
wherein:
(a) the visible light output produced during the excitation of the semiconductor nanophosphors is at least substantially white;
(b) the visible light output produced during the excitation of the semiconductor nanophosphors has a color rendering index (CRI) of 75 or higher; and
(c) the visible light output produced during the excitation of the semiconductor nanophosphors has a color temperature in one of the following ranges:
2,725±145° Kelvin;
3,045±175° Kelvin;
3,465±245° Kelvin;
3,985±275° Kelvin;
4,503±243° Kelvin;
5,028±283° Kelvin;
5,665±355° Kelvin; and
6,530±510° Kelvin.

2. The solid state light emitting device of claim 1, wherein:
the absorption spectrum of each of the semiconductor nanophosphors has an upper limit of approximately 460 nm or below, and
the plurality of semiconductor nanophosphors comprises:
a doped semiconductor nanophosphor of a type for re-emitting orange light;
a doped semiconductor nanophosphor of a type for re-emitting blue light; and
a doped semiconductor nanophosphor of a type for re-emitting green light.

3. The solid state light emitting device of claim 2, wherein each of the doped semiconductor nanophosphors being of a type excited in response to near UV electromagnetic energy in the range of 380-420 nm for re-emitting visible light of a different spectrum having substantially no overlap with absorption spectra of the doped semiconductor nanophosphors, for together producing visible light in the output of the device when the doped semiconductor nanophosphors are excited by near UV electromagnetic energy from the semiconductor chip.

4. The solid state light emitting device of claim 2, wherein the re-emitted visible light has substantially no overlap with absorption spectra of the semiconductor nanophosphors.

5. The solid state light emitting device of claim 2, wherein the plurality of doped semiconductor nanophosphors further comprises a doped semiconductor nanophosphor of a type excited for re-emitting yellowish-green or greenish-yellow light.

6. The solid state light emitting device of claim 2, wherein the visible light output produced during the near UV excitation of the doped semiconductor nanophosphors has a CRI of at least 80.

7. The solid state light emitting device of claim 1, wherein:
the absorption spectrum of each of the semiconductor nanophosphors has an upper limit of approximately 460 nm or below, and
the plurality of semiconductor nanophosphors comprises:
a doped semiconductor nanophosphor of a type for re-emitting red light;
a doped semiconductor nanophosphor of a type for re-emitting green light; and
a doped semiconductor nanophosphor of a type for re-emitting blue light.

8. The light fixture of claim 6, wherein the plurality of doped semiconductor nanophosphors further comprises a doped semiconductor nanophosphor of a type excited for re-emitting yellow light.

9. The light fixture of claim 7, wherein the visible light output produced during the excitation of the doped semiconductor nanophosphors has a CRI of at least 88.

10. The solid state light emitting device of claim 1, wherein the semiconductor chip is configured for producing electromagnetic energy of a wavelength in the range of 460 nm or below.

11. The solid state light emitting device of claim 1, further comprising:
at least one reflective surface within the package forming an optical integrating cavity;
wherein the semiconductor chip is positioned and oriented so that at least substantially all direct emissions from the semiconductor chip reflect at least once within the cavity.

12. The solid state light emitting device of claim 11, wherein the at least one reflective surface is diffusely reflective.

13. The solid state light emitting device of claim 11, wherein
a containment member is configured to contain the liquid or gas such that the liquid or gas fills at least a substantial portion of the optical integrating cavity; and
a light transmissive surface of the containment member forms an optical aperture.

14. The solid state light emitting device of claim 13, wherein the semiconductor chip is positioned and oriented relative to the container which contains the liquid or gas, so that any electromagnetic energy reaching the surface of the container forming the optical aperture, directly from the semiconductor chip, impacts the optical aperture at a sufficiently small angle as to be reflected back into the optical integrating cavity by total internal reflection at the optical aperture.

15. The solid state light emitting device of claim 14, wherein: the plurality of semiconductor nanophosphors are dispersed in light transmissive liquid, and the liquid is an oil or alcohol.

16. The solid state light emitting device of claim 14, wherein: the plurality of doped semiconductor nanophosphors are dispersed in light transmissive gas, and the light transmissive gas consists essentially of a gas or a combination of gases selected from the group consisting of: an inert gas, a hydrocarbon gas, hydrogen gas and nitrogen gas.

17. The solid state light emitting device of claim 1, wherein the liquid or gas is substantially color-neutral.

18. A solid state light emitting device, comprising:
a semiconductor chip for producing electromagnetic energy;
a package enclosing the semiconductor chip;
at least one reflective surface forming an optical integrating cavity within the package, wherein the semiconductor chip is positioned and oriented so that at least substantially all direct emissions from the semiconductor chip reflect at least once within the cavity;
a light transmissive gas or liquid material and a containment member configured to contain the material within the package such that the light transmissive material fills at least a substantial portion of the optical integrating cavity, a surface of a containment member forming an optical aperture to allow emission of light from the cavity for a light output of the device; and
a plurality of phosphors dispersed in the light transmissive gas or liquid material, each of the phosphors having a respective absorption spectrum encompassing an emission spectrum of the semiconductor chip for re-emitting visible light of a different spectrum, for together producing visible light in the output of the device when the phosphors are excited by electromagnetic energy from the semiconductor chip, wherein:
(a) the visible light output produced during the excitation of the phosphors is at least substantially white; and
(b) the visible light output produced during the excitation of the phosphors has a color rendering index (CRI) of 75 or higher.

19. The solid state light emitting device of claim 18, wherein the phosphors in the device comprise a plurality of semiconductor nanophosphors.

20. The solid state light emitting device of claim 19, wherein emissions of the semiconductor nanophosphors cause the visible light output of the device to have a color temperature in one of the following ranges:
2,725±145° Kelvin;
3,045±175° Kelvin;
3,465±245° Kelvin;
3,985±275° Kelvin;
4,503±243° Kelvin;
5,028±283° Kelvin;
5,665±355° Kelvin; and
6,530±510° Kelvin.

21. The solid state light emitting device of claim 18, wherein the semiconductor chip is positioned and oriented relative to the containment member so that any electromagnetic energy reaching the surface of the containment member forming the optical aperture, directly from the semiconductor chip, impacts the optical aperture at a sufficiently small angle as to be reflected back into the optical integrating cavity by total internal reflection at the optical aperture.

22. The solid state light emitting device of claim 21, wherein the at least one reflective surface is diffusely reflective.

23. The solid state light emitting device of claim 18, wherein the light transmissive material is an oil or alcohol.

24. The solid state light emitting device of claim 18, wherein the light transmissive material is a gas or a combination of gases selected from the group consisting of: an inert gas, a hydrocarbon gas, hydrogen gas, and nitrogen gas.
